(19) United States
(12) Patent Application Publication
(10) Pub. No.: US 2013/0205075 A1
(43) Pub. Date: Aug. 8, 2013

(54) NONVOLATILE MEMORY DEVICE AND MEMORY CARD INCLUDING THE SAME

(71) Applicant: SAMSUNG ELECTRONICS CO., LTD., Suwon-Si (KR)

(72) Inventors: Moshe TWITTO, Ramat Gan (IL); Rutie ADAR, Ramat Gan (IL); Shay LANDIS, Ramat Gan (IL)

(73) Assignee: SAMSUNG ELECTRONICS CO., LTD., Suwon-Si (KR)

(21) Appl. No.: 13/756,784

(22) Filed: Feb. 1, 2013

(30) Foreign Application Priority Data
Feb. 2, 2012 (KR) 10-2012-0010862

(51) Int. Cl. G11C 16/26; G06F 12/02; G11C 16/34

(52) U.S. Cl. CPC G11C 16/26; G11C 16/3459; G06F 12/0246
USPC 711/103; 365/185.25; 365/185.22; 365/185.09; 365/185.11

(57) ABSTRACT

There is provided a nonvolatile memory device including a memory cell array including nonvolatile memory cells, a battery not supplied with external power and configured to store a charged voltage, a sensing unit configured to sense a degradation state of the nonvolatile memory cells of the memory cell array, and a trigger circuit configured to transmit a refresh trigger signal based on the sensing result, wherein the nonvolatile memory cells of the memory cell array are refreshed using the charged voltage provided by the battery in response to the trigger signal transmitted from the trigger circuit.

### CROSS-REFERENCE TO RELATED APPLICATION

This application claims priority from Korean Patent Application No. 10-2012-0010862 filed on Feb. 2, 2012 in the Korean Intellectual Property Office, the disclosure of which is incorporated herein by reference in its entirety.

### BACKGROUND

1. Field of the Invention

Example embodiments relate to a nonvolatile memory device and a memory card including the same.

2. Description of the Related Art

Memory devices are classified into volatile memory devices and nonvolatile memory devices. The volatile memory devices lose data if the power supply is turned off. The nonvolatile memory devices retain data even if the power supply is turned off.

Examples of the nonvolatile memory devices include read-only memories (ROMs) and electrically erasable programmable read-only memories (EEPROMs).

The structure and operation of flash memory devices introduced as flash EEPROMs are different from those of conventional EEPROMs. A flash memory device may perform an electric erase operation on a block-by-block basis and a program operation on a bit-by-bit basis.

Threshold voltages of a plurality of programmed memory cells included in a flash memory device can change due to various causes including floating gate coupling and charge loss over time.

A change in the threshold voltages of the memory cells can undermine the reliability of read data.

### SUMMARY

Some example embodiments provide a nonvolatile memory device that improves the reliability of read data.

Some example embodiments provide a memory card that improves the reliability of read data.

However, example embodiments are not restricted to the ones set forth herein. Example embodiments will become more apparent to one of ordinary skill in the art to which the example embodiments pertain by referencing the detailed description given below.

According to an example embodiment, there is provided a nonvolatile memory device comprising, a memory cell array comprising nonvolatile memory cells, a battery not supplied with external power and configured to store a charged voltage, a sensing unit sensing a degradation state of the nonvolatile memory cells of the memory cell array, and a trigger circuit transmitting a refresh trigger signal based on the sensing result, wherein the nonvolatile memory cells of the memory cell array are refreshed using the charged voltage provided by the battery in response to the trigger signal transmitted from the trigger circuit.

According to another example embodiment, there is provided a nonvolatile memory device comprising, a memory cell array comprising a plurality of blocks, a battery storing and supplying power, a trigger circuit controlling the memory cell array to be refreshed selectively, and a page buffer receiving a refresh command from the trigger circuit, wherein the memory cell array is refreshed using the power provided by the battery without requiring an external power supply voltage.

According to an example embodiment, there is provided a memory card comprising, a nonvolatile memory device comprising a memory cell array that comprises a plurality of blocks, a card interface for communication with a host, and a memory controller controlling communication between the nonvolatile memory device and the card interface, wherein the nonvolatile memory device comprises, a memory cell array comprising nonvolatile memory cells, a battery not supplied with external power and configured to store a charged voltage, a sensing unit sensing a degradation state of the nonvolatile memory cells of the memory cell array, a trigger circuit transmitting a refresh trigger signal based on the sensing result, and a control logic driven by the charged voltage supplied from the battery and refreshing the nonvolatile memory cells of the memory cell array using the charged voltage in response to the refresh trigger signal transmitted from the trigger circuit.

### BRIEF DESCRIPTION OF THE DRAWINGS

The above and other features and advantages of the example embodiments will become more apparent by describing in detail some example embodiments with reference to the attached drawings in which:

FIG. 1 is a graph illustrating the charge loss of a single-level cell (SLC) flash memory device;

FIG. 2 is a graph illustrating the charge loss of a 2-bit multi-level cell (MLC) flash memory device;

FIG. 3 is a block diagram of a nonvolatile memory device 100 according to example embodiments;

FIG. 4 is a graph illustrating a refresh method according to an example embodiment;

FIG. 5 is a diagram illustrating a refresh method according to another example embodiment;

FIG. 6 is a block diagram of a memory card 300 including a nonvolatile memory device 330 according to an example embodiment;

FIG. 7 is a flowchart illustrating a method of refreshing a nonvolatile memory device according to an example embodiment;

FIG. 8 is a block diagram of an electronic device 700 including a nonvolatile memory device 760 according to an example embodiment;

FIG. 9 is a block diagram of an electronic device 800 including a nonvolatile memory device 840 according to another example embodiment;

FIG. 10 is a block diagram of an electronic device 900 including a nonvolatile memory device 940 according to another example embodiment;

FIG. 11 is a block diagram of an electronic device 1000 including a nonvolatile memory device 1050 according to another example embodiment; and

FIG. 12 is a block diagram of an electronic device 1100 including a nonvolatile memory device 1160 according to another example embodiment.

### DETAILED DESCRIPTION OF THE EMBODIMENTS

Example embodiments will now be described more fully hereinafter with reference to the accompanying drawings, in which some example embodiments are shown. This invention may, however, be embodied in different forms and should not be construed as limited to the example embodiments set forth herein. Rather, these example embodiments are provided so that this disclosure will be thorough and complete, and will filly convey the scope of the invention to those skilled in the art. The same reference numbers indicate the same components throughout the specification. In the attached figures, the thickness of layers and regions is exaggerated for clarity.

It will also be understood that when a layer is referred to as being “on” another layer or substrate, it can be directly on the other layer or substrate, or intervening layers may also be present. In contrast, when an element is referred to as being “directly on” another element, there are no intervening elements present.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The use of the terms “a” and “an” and “the” and similar referents in the context of describing the invention (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted.

Unless defined otherwise, all technical and scientific terms used herein have the same meaning as commonly understood by one of ordinary skill in the art to which this invention belongs. It is noted that the use of any and all examples, or exemplary terms provided herein is intended merely to better illuminate the invention and is not a limitation on the scope of the invention unless otherwise specified. Further, unless defined otherwise, all terms defined in generally used dictionaries may not be overly interpreted.

Example embodiments will be described with reference to perspective views, cross-sectional views, and/or plan views, in which some example embodiments are shown. Thus, the profile of an example view may be modified according to manufacturing techniques and/or allowances. The example embodiments are not intended to limit the scope but cover all changes and modifications that can be caused due to a change in manufacturing process. Thus, regions shown in the drawings are illustrated in schematic form and the shapes of the regions are presented simply by way of illustration and not as a limitation.

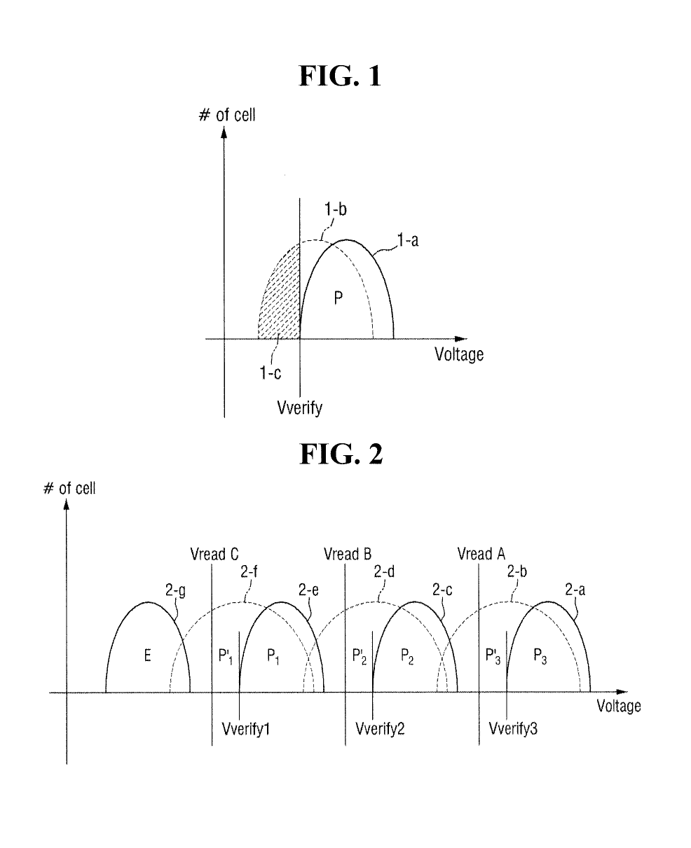

FIG. 1 is a graph illustrating the charge loss of a single-level cell (SLC) flash memory device.

Referring to FIG. 1, charge loss is a phenomenon in which some of electrons trapped in a storage layer (e.g., a floating gate) or a tunnel oxide layer of a flash memory device escape from the storage layer or the tunnel oxide layer as the time elapses. As the number of times that program and erase operations are performed increases, the tunnel oxide layer is degraded, thus increasing the charge loss.

The x axis represents voltage, and the y axis represents the number of memory cells. A first programmed state distribution 1-a is a programmed state distribution immediately after a program operation (i.e., before a charge loss occurs), and a second programmed state distribution 1-b is a programmed state distribution after a charge loss occurs. A charge loss causes the first programmed state distribution 1-a to shift to the second programmed state distribution 1-b.

Therefore, the first programmed state distribution 1-a is located to the right of a verify voltage Vverify, whereas a part 1-c of the second programmed state distribution is located to the left of the verify voltage Vverify. If the number of nonvolatile memory cells corresponding to the part 1-c of the second programmed state distribution 1-b is large, the nonvolatile memory cells corresponding to the part 1-c cannot be corrected using error correction code (ECC).

FIG. 2 is a graph illustrating the charge loss of a 2-bit multi-level cell (MLC) flash memory device.

To program k bits into one memory cell of an MLC nonvolatile memory device, any one of 2 k threshold voltages should be formed in the memory cell. If 2 bits are stored in one memory cell, threshold voltages of memory cells programmed with the same data may form a certain range of threshold voltage distributions due to a delicate difference in electrical properties of memory cells. The threshold voltage distributions may correspond respectively to 2 k data values that can be generated by the k bits.

Referring to FIG. 2, a 2-bit MLC nonvolatile memory device has three programmed state threshold voltage distributions (i.e., state distributions immediately after a program operation) PI (2-e), P2 (2-c) and P3 (2-a) and one erased state threshold voltage distribution E (2-g). The programmed state threshold voltage distributions PI (2-e), P2 (2-c) and P3 (2-a) do not overlap at all since no charge loss occurs immediately after a program operation. Each programmed state threshold voltage distribution has a read voltage. Therefore, the 2-bit MLC nonvolatile memory device has three read voltages VreadA, VreadB, and VreadC. The read voltages VreadA, VreadB and VreadC may be default voltages given in a manufacturing process. In the drawing, the 2-bit MLC nonvolatile memory device is illustrated as an example. However, example embodiments may vary and are not limited to this example. A 3-bit MLC nonvolatile memory may have seven programmed state threshold voltage distributions and one erased state threshold voltage distribution, and a 4-bit MLC nonvolatile memory may have fifteen programmed state threshold voltage distributions and one erased state threshold voltage distribution.

As the 2-bit MLC nonvolatile memory device is programmed over time or repeatedly programmed and erased over time, properties of flash memory cells are degraded, causing a charge loss. In FIG. 2, an example of the programmed and erased state threshold voltage distributions that can be changed by the charge loss is illustrated.

As described above with reference to FIG. 1, a nonvolatile memory device may experience a charge loss defined as the release of electrons from a floating gate or a tunnel oxide layer over time. As the nonvolatile memory device is programmed and erased repeatedly, the tunnel oxide layer may be degraded, thus increasing the charge loss. Since the charge loss can reduce threshold voltages, the distribution of threshold voltages may be shifted to the left.

Referring to FIG. 2, adjacent threshold voltage distributions may overlap each other. If threshold voltage distributions overlap, data read if a certain read voltage is applied may have a greater number of errors. For example, if a memory cell is on when VreadA is applied, data read from the memory cell may belong to P2. If the memory cell is off, the read data may belong to P3. However, in an overlap region of threshold voltage distributions, even if a memory cell is in the state of P3, it can be read while it is on, thus creating an error bit. Therefore, if threshold voltage distributions overlap, read data may include a greater number of error bits.

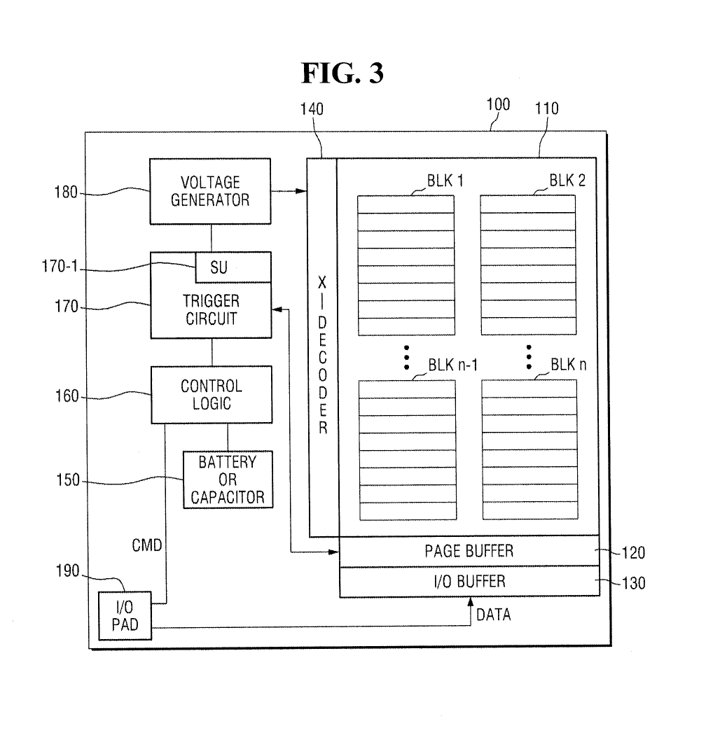

FIG. 3 is a block diagram of a nonvolatile memory device 100 according to example embodiments.

In FIG. 3, a NAND flash memory device is used as an example of the nonvolatile memory device 100. However, example embodiments may vary and are not limited to this example. The nonvolatile memory device 100 may include a plurality of NAND flash memory devices. The nonvolatile memory device 100 includes a planar memory cell structure and a 3D memory cell structure formed by stacking.

Referring to FIG. 3, the nonvolatile memory device 100 includes a memory cell array 110 that includes a plurality of blocks BLK1 through BLKn, a battery or capacitor 150, a sensing unit 170-1 that senses the degradation state of nonvolatile memory cells in the memory cell array 110, a trigger circuit 171 that transmits a refresh trigger signal based on the sensing result, and a control logic 160 that controls the blocks of the memory cell array 110 to be selectively refreshed. The control logic 160 is driven by a charged voltage supplied from the battery or capacitor 150, not by an external power supply voltage Vcc, and refreshes the nonvolatile memory cells of the memory cell array 110 in response to a trigger signal transmitted from the trigger circuit 170.

Referring to FIG. 3, the nonvolatile memory device 100 may include the memory cell array 110, an X-decoder (a row selection circuit) 140, a voltage generator 180, an input/output (I/O) pad 190, an I/O buffer 130, a page buffer 120, the control logic 160, the trigger circuit 170, the sensing unit 170-1, and the battery or capacitor 150.

The memory cell array 110 includes a plurality of blocks. Each block includes a plurality of word lines W/L and a plurality of bit lines B/L. Each memory cell may store 1-bit data or M-bit data (where M is a natural number greater than two). Each memory cell may be implemented as a memory cell having a charge storage layer such as a floating gate or a charge trapping layer or a memory cell having a variable resistor.

The memory cell array 110 may include a plurality of blocks and a plurality of pages. One block includes a plurality of pages. A page may be a unit of program and read operations, and a block may be a unit of erase operation. In a read operation, data programmed into one page is read.

The memory cell array 110 may be implemented as a single-layer array structure (or a 2D array structure) or a multi-layer array structure (or a 3D array structure).

The control logic 160 controls the overall operation of the nonvolatile memory device 100. If a command CMD is input from a system, the control logic 160 interprets the command CMD and controls the nonvolatile memory device 100 to perform an operation (e.g., a program operation, a read operation, a read retry operation, or an erase operation) corresponding to the interpreted command CMD. The control logic 160 may control the blocks of the memory cell array 110 to be selectively refreshed. According to an example embodiment, the control logic 160 may control the entire memory cell array 110 to be refreshed or control one or a plurality of blocks selected from the blocks of the memory cell array 110 to be refreshed.

The X-decoder 140 is controlled by the control logic 160 and drives at least one of the word lines W/L included in the memory cell array 110 according to a row address.

The voltage generator 180 is controlled by the control logic 160 to generate one or more voltages required for a program operation, a read operation, a refresh operation or an erase operation. The generated voltages are provided to one or more memory cells selected by the X-decoder 140.

The page buffer 120 is controlled by the control logic 160 and operates as a sense amplifier or a write driver according to an operation mode (e.g., a read operation or a program operation). As will be described later, the page buffer 120 may receive a refresh command from the trigger circuit 170.

The I/O pad 190 and the I/O buffer 130 may serve as an I/O path of data exchanged between an external device (e.g., a controller or a host) and the nonvolatile memory device 100.

The sensing unit 170-1 senses the degradation state of the nonvolatile memory cells. Degradation of the memory cells refers to a change in the programmed state distribution of the memory cells due to the charge loss described above with reference to FIG. 1. The sensing unit 170-1 may sense an amount of charge loss of the memory cells in the memory cell array 110. Therefore, the sensing unit 170-1 senses the degree of deterioration of the memory cells and provides the sensing result to the trigger circuit 170.

The trigger circuit 170 may control the refreshing of the memory cell array 110. The trigger circuit 170 may determine whether to refresh the memory cells of the memory cell array 110 based on the result of sensing the deterioration state of the memory cell array 110 provided by the sensing unit 170-1. If the charge loss of the memory cells of the memory cell array 110 exceeds a given reference value, the trigger circuit 170 may determine to refresh the memory cell array 110. The trigger circuit 170 may provide a refresh command to the page buffer 120.

According to another example embodiment, the nonvolatile memory device 100 may refresh the memory cell array 110 periodically, regardless of the determination of the trigger circuit 170. The control logic 160 may not sense the state of the memory cell array 110. Instead, the control logic 160 may control the memory cell array 110 to be refreshed periodically. The control logic 160 may determine to refresh the memory cell array 110 using an internal clock of the nonvolatile memory device 100. Controlled by the control logic 160, the memory cell array 110 may be refreshed periodically in synchronization with the internal clock.

The battery or capacitor 150 is not supplied with external power and stores a charged voltage. The battery or capacitor 150 may store power and supply the power to the nonvolatile memory device 100 if external power is not available. The battery or capacitor 150 may be a micro battery, a micro capacitor, a capacitor, or a super capacitor. The battery or capacitor 150 may be disposed inside or outside the memory cell array 110 and is electrically connected to the control logic 160, the trigger circuit 170, and the voltage generator 180. The nonvolatile memory device 100 can perform a refresh operation using power provided by the battery or capacitor 150. If the external power supply voltage Vcc is not available, the nonvolatile memory device 100 can refresh the memory cell array 110 using power provided by the battery or capacitor 150. For example, if a secure digital (SD) card including a nonvolatile memory is connected to a host and supplied with an external power supply voltage, the battery or capacitor 150 may be charged with the external power supply voltage. After the SD card is disconnected from the host, the battery or capacitor 150 may supply a voltage to the nonvolatile memory. Therefore, even without an external power supply, the nonvolatile memory can perform a refresh. The refresh encompasses a refresh using the trigger circuit 170 and a periodic refresh. Since the nonvolatile memory can be refreshed using the battery or capacitor 150 if not provided with the external power supply voltage, the charge loss of the nonvolatile memory can be reduced even if the SD card is disconnected from the host. This can improve the reliability of the nonvolatile memory.

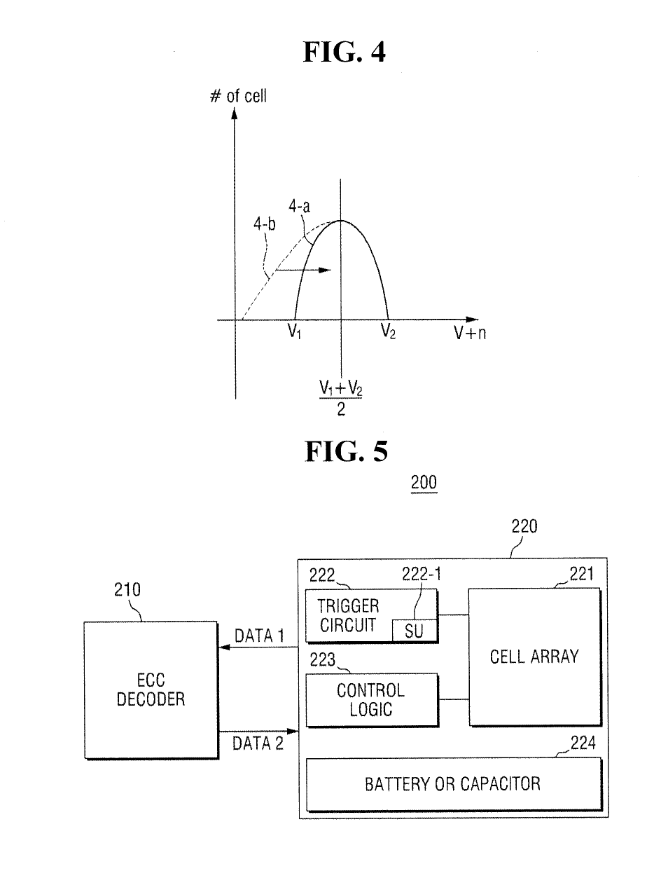

FIG. 4 is a graph illustrating a refresh method according to an example embodiment.

Referring to FIG. 4, the x axis represents the threshold voltage of nonvolatile memory cells, and the y axis represents the number of nonvolatile memory cells. In FIG. 4, a given threshold voltage distribution 4-a of memory cells and a threshold voltage distribution 4-b of the memory cells after a charge loss are illustrated. The threshold voltage distribution 4-a given when a nonvolatile memory device is manufactured includes a minimum threshold voltage V1 and a maximum threshold voltage V2. The minimum threshold voltage V1 is used as a verify voltage in the manufacturing process. For ease of description, the minimum threshold voltage V1 will be referred to as a first verify voltage. Referring to FIGS. 3 and 4, a refresh increases threshold voltages of memory cells included in blocks of a memory cell array to a center ([V1+V2]/2) of the given threshold voltage distribution 4-a without using error bit-corrected data.

A refresh increases threshold voltages of degraded memory cells using a second verify voltage that is greater than the first verify voltage used for data program verification. The second verify voltage may be a median voltage ([V1+V2]/2) of the minimum threshold voltage V1 and the maximum threshold voltage V2 of the given program data distribution 4-a.

Therefore, power consumed by an ECC decoder for error bit correction can be saved, and thus the memory cell array can be refreshed with low power consumption using power provided by a power storage device.

FIG. 5 is a diagram illustrating a refresh method according to another example embodiment.

In FIG. 5, an ECC decoder 210 and a nonvolatile memory device 220 are illustrated. The ECC decoder 210 corrects error bits of read data. Read first data DATA1 is transmitted to the ECC decoder 210, and the ECC decoder 210 corrects error bits of the first data DATA1 using parity bits.

Referring to FIGS. 3 and 5, if a trigger circuit 222 determines to refresh a memory cell array 221 based on a result value indicating the degree of degradation of memory cells that is sensed by a sensing unit 222-1, the memory cell array 221 is refreshed using power provided by a battery or capacitor 224. A control logic 223 controls the overall operation of the nonvolatile memory device 220. Referring to FIG. 5, data read from a memory cell is provided to the ECC decoder 210, and the ECC decoder 210 generates second data DATA2 by correcting error bits of the read data and provides the second data DATA2 to the nonvolatile memory device 220. The nonvolatile memory device 220 refreshes the memory cell array 221 using the second data DATA2. The use of the ECC decoder 210 may increase power consumption. However, the use of the error bit-corrected second data DATA2 enables the formation of a more accurate state distribution of the nonvolatile memory device 220 during a refresh.

The ECC decoder 210 may perform error correction using, but not limited to, low density parity check (LDPC) code, BCH code, turbo code, Reed-Solomon code, convolution code, recursive systematic code (RSC), or coded modulation such as trellis-coded modulation (TCM) or block coded modulation (BCM).

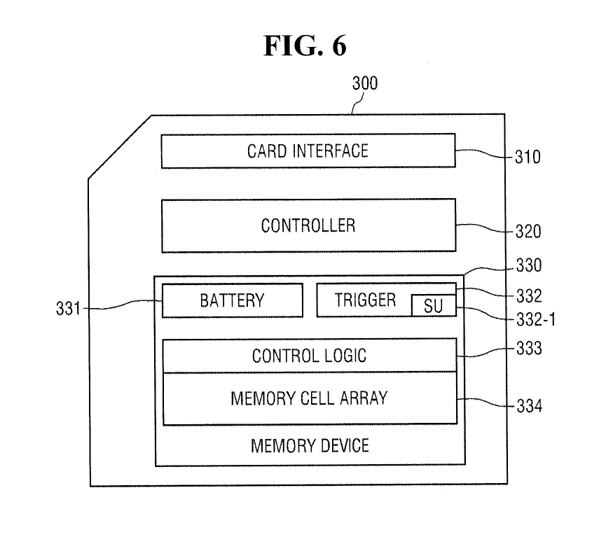

FIG. 6 is a block diagram of a memory card 300 including a nonvolatile memory device 330 according to an example embodiment.

Referring to FIG. 6, the memory card 300 includes a card interface 310, a controller 320, and the nonvolatile memory device 330.

The card interface 310 may interface data exchange between a host HOST and the controller 320 according to a communication protocol of the host HOST that can communicate with the memory card 300. The memory card 300 may exchange data with the host HOST through the card interface 310. The card interface 310 may be an SD card interface, a multimedia card (MMC) interface, an eMMC card interface, or a universal serial bus (USB) drive interface.

The controller 320 controls the overall operation of the memory card 300 and controls data exchange between the card interface 310 and the nonvolatile memory device 330. The controller 320 may transmit or receive data to be read or written via a data bus DATA connected to each of the card interface 310 and the nonvolatile memory device 330.

The nonvolatile memory device 330 includes a memory cell array 334, a control logic 333, a trigger circuit 332, a sensing unit 332-1, and a battery 331. Elements of the nonvolatile memory device 330 may be identical or similar to those of the nonvolatile memory device 100 shown in FIG. 3.

The memory cell array 334 includes a plurality of blocks. One block includes a plurality of pages. A page may be a unit of program and read operations, and a block may be a unit of erase operation. In a read operation, data programmed into one page is read.

The control logic 333 controls the overall operation of the nonvolatile memory device 330. The control logic 333 interprets a command CMD and controls the nonvolatile memory device 330 to perform an operation (e.g., a program operation, a read operation, a read retry operation, or an erase operation) corresponding to the interpreted command CMD. The control logic 333 may control the blocks of the memory cell array 334 to be selectively refreshed. According to an example embodiment, the control logic 333 may control the entire memory cell array 334 to be refreshed or control only some blocks of the memory cell array 334 to be refreshed.

The sensing unit 332-1 senses the degradation state of nonvolatile memory cells as described above with reference to FIG. 3. The sensing unit 332-1 provides the sensing result to the trigger circuit 332.

The trigger circuit 332 may control the refreshing of the memory cell array 334. The trigger circuit 332 may determine whether to refresh the memory cell array 334 based on the result of sensing the deterioration state of the memory cell array 334 provided by the sensing unit 332-1. The trigger circuit 332 transmits a refresh trigger signal to the control logic 333. If the charge loss of the memory cells of the memory cell array 334 exceeds a given reference value, the trigger circuit 332 may determine to refresh the memory cell array 334.

The battery 331 stores power and supplies the power to the nonvolatile memory device 330 if external power is not available. The battery 331 is not supplied with external power and stores a charged voltage. The battery 331 may be a micro battery, a micro capacitor, a capacitor, or a super capacitor. The battery 331 may be disposed inside or outside the memory cell array 334 and is electrically connected to the control logic 333 and the trigger circuit 332. The nonvolatile memory device 330 can perform a refresh operation using power provided by the battery 331. If an external power supply voltage is not available, the nonvolatile memory device 330 can refresh the memory cell array 334 using power provided by the battery 331.

Therefore, even if the memory card 300 is disconnected from the host HOST, the battery 331 provides a voltage to the nonvolatile memory device 330. The nonvolatile memory device 330 can perform a refresh without intervention of the controller 320. Therefore, the nonvolatile memory device 330 can be refreshed without the external power supply voltage. Since the nonvolatile memory device 330 can be refreshed using the battery 331 if not provided with the external power supply voltage, the charge loss of the nonvolatile memory device 300 can be reduced even if the memory card 300 is disconnected from the host HOST. This can improve the reliability of the nonvolatile memory device 330.

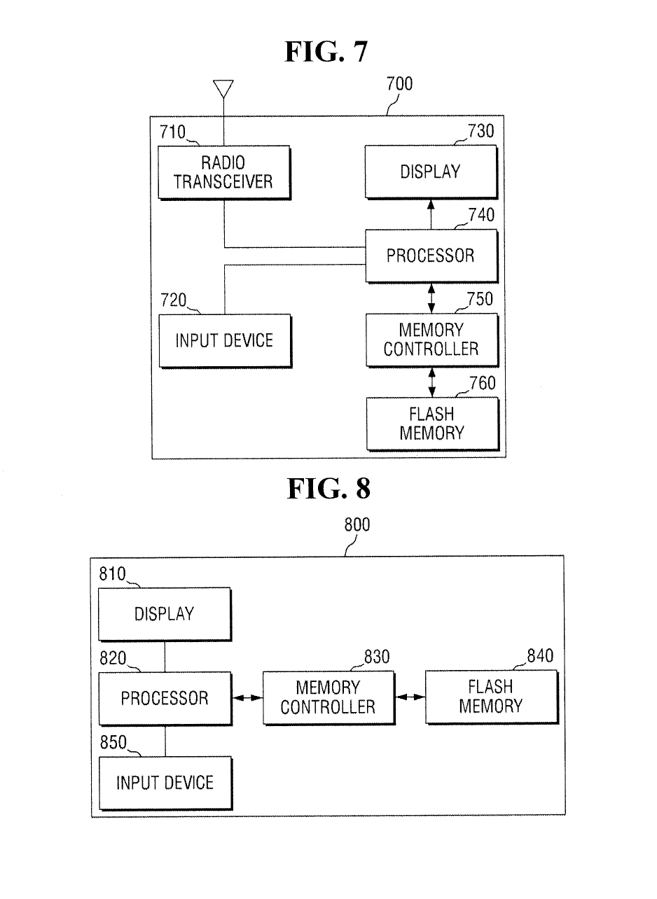

FIG. 7 is a flowchart illustrating a method of refreshing a nonvolatile memory device according to an example embodiment.

Referring to FIG. 7, a charged voltage is stored, and the stored voltage is provided to a nonvolatile memory device without an external power supply (operation S700). Referring to FIGS. 3 and 7, the battery or capacitor 150 stores a charged voltage and provides the stored voltage to the nonvolatile memory device without an external power supply. The degradation state of memory cells of the nonvolatile memory device is sensed (operation S710). Referring to FIGS. 3 and 7, the sensing unit 170-1 senses the degradation state of the memory cells corresponding to the amount of charge loss of the memory cells. A trigger signal is transmitted to a control logic based on the sensing result (operation S720). Referring to FIGS. 3 and 7, the trigger circuit 170 transmits a refresh trigger signal to the control logic 160 based on the sensing result of the sensing unit 170-1. The nonvolatile memory device refreshes the nonvolatile memory cells using the stored voltage,without an external power supply, in response to the trigger signal (operation S730).

FIG. 8 is a block diagram of an electronic device 700 including a nonvolatile memory device 760 according to an example embodiment.

Referring to FIG. 8, the electronic device 700 may be a cellular phone, a smart phone or a table personal computer (PC). The electronic device 700 may include the nonvolatile memory device 760 that can be implemented as a flash memory device and a memory controller 750 that can control the operation of the nonvolatile memory device 760.

The nonvolatile memory device 760 may be identical or similar to the nonvolatile memory device 100 described above with reference to FIG. 3. Without an external power supply voltage, the nonvolatile memory device 760 may refresh a memory cell array by sensing the cell state of the memory cell array or may refresh the memory cell array periodically.

The memory controller 750 is controlled by a processor 740 that controls the overall operation of the electronic device 700.

The memory controller 750 that is controlled by the processor 740 may control data stored in the nonvolatile memory device 760 to be displayed on a display 730.

A radio transceiver 710 may receive or transmit radio signals through an antenna ANT. For example, the radio transceiver 710 may convert a radio signal received through the antenna ANT into a signal that can be processed by the processor 740. Therefore, the processor 740 may process the signal output from the radio transceiver 710 and store the processed signal in the nonvolatile memory device 760 via the memory controller 750 or display the processed signal on the display 730.

The radio transceiver 710 may convert a signal output from the processor 710 into a radio signal and transmit the radio signal through the antenna ANT.

An input device 720 is a device by which a control signal for controlling the operation of the processor 740 or data to be processed by the processor 740 can be input. The input device 720 may be implemented as a pointing device such as a touchpad or computer mouse, a keypad, or a keyboard.

The processor 740 may control the display 730 to display data output from the nonvolatile memory device 760, a radio signal output from the radio transceiver 710, or data output from the input device 720.

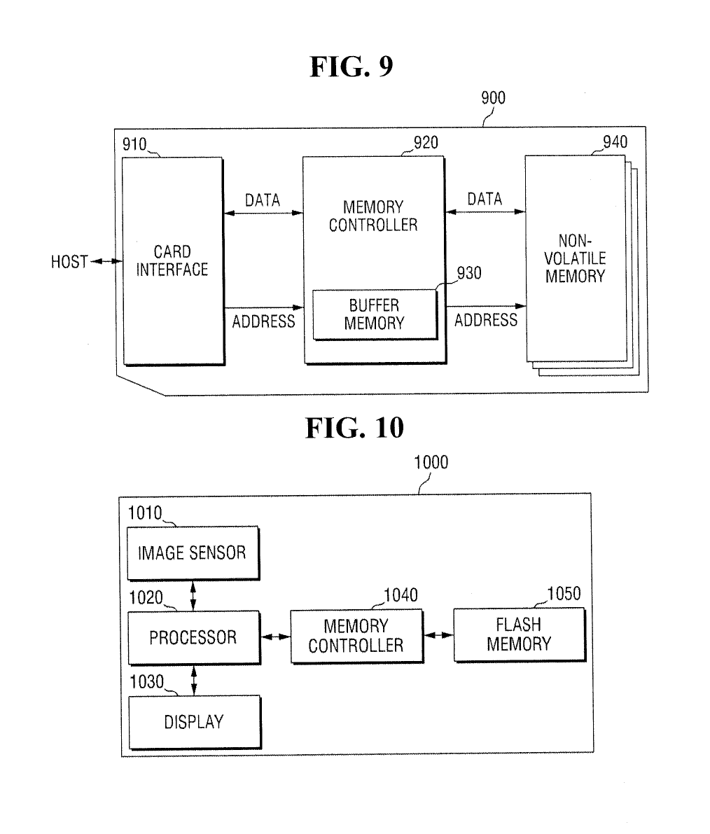

FIG. 9 is a block diagram of an electronic device 800 including a nonvolatile memory device 840 according to another example embodiment.

Referring to FIG. 9, the electronic device 800 may be a data processor such as a PC, a table computer, a net-book, an e-reader, a personal digital assistant (PDA), a portable multimedia player (PMP), an MP3 player, or an MP4 player. The electronic device 800 may include the nonvolatile memory device 840 such as a flash memory device and a memory controller 830 that can control the operation of the nonvolatile memory device 840.

The nonvolatile memory device 840 may be identical or similar to the nonvolatile memory device 100 described above with reference to FIG. 3. Without an external power supply voltage, the nonvolatile memory device 840 may refresh a memory cell array by sensing the cell state of the memory cell array or may refresh the memory cell array periodically.

The electronic device 800 may include a processor 820 for controlling the overall operation of the electronic device 800. The memory controller 830 is controlled by the processor 820.

In response to an input signal generated by an input device 850, the processor 820 may display data stored in the nonvolatile memory device 840 on a display 810. The input device 850 may be, for example, a pointing device such as a touchpad or a computer mouse, a keypad, or a keyboard.

FIG. 10 is a block diagram of an electronic device 900 including a nonvolatile memory device 940 according to another example embodiment.

Referring to FIG. 10, the electronic device 900 includes a card interface 910, a memory controller 920, and the nonvolatile memory device 940 (e.g., a flash memory device).

The electronic device 900 may perform data communication with a host HOST through the card interface 910. The card interface 910 may be, but is not limited to, an SD card interface or an eMMC or MMC interface. The card interface 910 may perform data communication between the host HOST and the memory controller 920 according to a communication protocol of the host HOST that can communicate with the electronic device 900.

The memory controller 920 may control the overall operation of the electronic device 900 and control data exchange between the card interface 910 and the nonvolatile memory device 940.

A buffer memory 930 included in the memory controller 920 may store various data for controlling the overall operation of the electronic device 900. The memory controller 920 may be connected to the card interface 910 and the nonvolatile memory device 940 through a data bus DATA and a logical address bus LOGICAL ADDRESS.

The memory controller 920 may receive an address of read data or write data from the card interface 910 through the logical address bus LOGICAL ADDRESS and transmit the received address to the nonvolatile memory device 940 through a physical address bus PHYSICAL ADDRESS.

The memory controller 920 may receive or transmit read data or write data through the data bus DATA that is connected to each of the card interface 910 and the nonvolatile memory device 940.

The memory controller 920 may perform both a write operation and a read operation.

The nonvolatile memory device 940 may be identical or similar to the nonvolatile memory device 100 described above with reference to FIG. 3. Without an external power supply voltage, the nonvolatile memory device 940 may refresh a memory cell array by sensing the cell state of the memory cell array or may refresh the memory cell array periodically.

If the electronic device 900 of FIG. 10 is connected to the host HOST such as a PC, a table PC, a digital camera, a digital audio player, a mobile phone, console video game hardware or a digital settop box, the host HOST may receive data stored in the nonvolatile memory device 940 or transmit data to the nonvolatile memory device 940 through the card interface 910 and the memory controller 920.

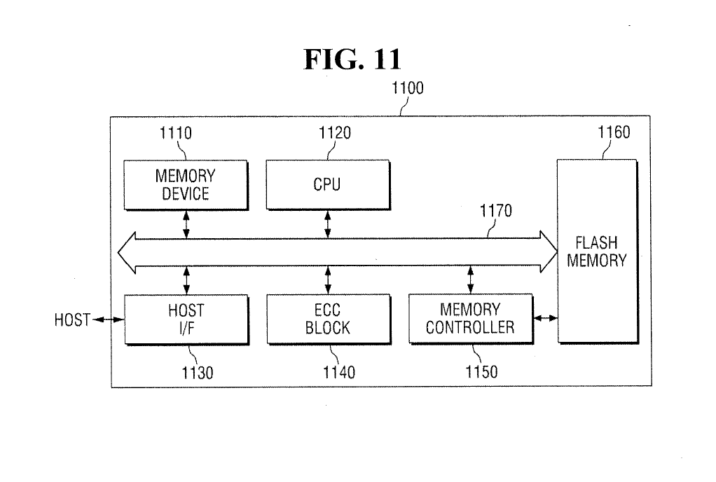

FIG. 11 is a block diagram of an electronic device 1000 including a nonvolatile memory device 1050 according to another example embodiment.

Referring to FIG. 11, the electronic device 1000 includes the nonvolatile memory device 1050 such as a flash memory device, a memory controller 1040 that controls the data processing operation of the nonvolatile memory device 1050, and a processor 1020 that controls the overall operation of the electronic device 1000.

The nonvolatile memory device 1050 may be identical or similar to the nonvolatile memory device 100 described above with reference to FIG. 3. Without an external power supply voltage, the nonvolatile memory device 1050 may refresh a memory cell array by sensing the cell state of the memory cell array or may refresh the memory cell array periodically.

An image sensor 1010 of the electronic device 1000 converts an optical signal into a digital signal, and the digital signal is stored in the nonvolatile memory device 1050 or displayed on a display 1030 under the control of the processor 1020. The digital signal stored in the nonvolatile memory device 1050 is displayed on the display 1030 under the control of the processor 1020.

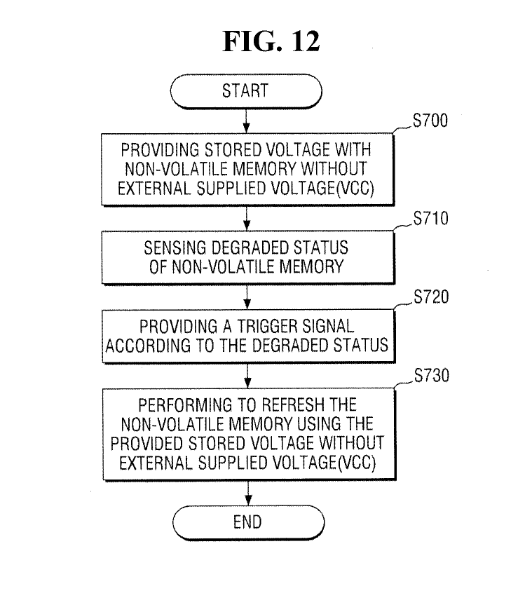

FIG. 12 is a block diagram of an electronic device 1100 including a nonvolatile memory device 1160 according to another example embodiment.

Referring to FIG. 12, the electronic device 1100 includes the nonvolatile memory device 1160 such as a flash memory device, a memory controller 1150 that controls the operation of the nonvolatile memory device 1160, and a central processing unit (CPU) 1120 that controls the overall operation of the electronic device 1100.

The electronic device 1100 includes a memory device 1110 that can be used as an operation memory of the CPU 1120. The memory device 1110 may be implemented as a nonvolatile memory such as a read-only memory (ROM) or a volatile memory such as a dynamic random access memory (DRAM).

The nonvolatile memory device 1160 may be identical or similar to the nonvolatile memory device 100 described above with reference to FIG. 3. Without an external power supply voltage, the nonvolatile memory device 1160 may refresh a memory cell array by sensing the cell state of the memory cell array or may refresh the memory cell array periodically.

A host HOST connected to the electronic device 1100 may exchange data with the nonvolatile memory device 1160 through the memory controller 1150 and a host interface 1130. The memory controller 1150 may function as a memory interface such as a flash memory interface.

The electronic device 1100 may further include an ECC block 1140. The ECC block 1140 controlled by the CPU 1120 may detect and correct errors included in data read from the nonvolatile memory device 1160 through the memory controller 1150.

The CPU 1120 may control data exchange between the memory controller 1150, the ECC block 1140, the host interface 1130, and the memory device 1110 through a bus 1170. The electronic device 1100 may be implemented as a USB memory drive or a memory stick.

In concluding the detailed description, those skilled in the art will appreciate that many variations and modifications can be made to the example embodiments shown without substantially departing from the example embodiments. Therefore, the disclosed example embodiments are used in a generic and descriptive sense only and not for purposes of limitation.

What is claimed is:

1. A nonvolatile memory device comprising:
a memory cell array including nonvolatile memory cells;
a battery not supplied with external power and configured to store a charged voltage;
a sensing unit configured to sense a degradation state of the nonvolatile memory cells of the memory cell array; and
a trigger circuit configured to transmit a refresh trigger signal based on the sensing result,
wherein the nonvolatile memory cells of the memory cell array are refreshed using the charged voltage provided by the battery in response to the trigger signal transmitted from the trigger circuit.

2. The nonvolatile memory device of claim 1, wherein the refreshing of the nonvolatile memory cells does not use error bit-corrected data and increases threshold voltages of degraded nonvolatile memory cells using a second verify voltage that is greater than a first verify voltage used for data program verification.

3. The nonvolatile memory device of claim 2, wherein the second verify voltage is a median voltage of a minimum threshold voltage and a maximum threshold voltage of a program data distribution.

4. The nonvolatile memory device of claim 1, wherein the nonvolatile memory cells are refreshed using data obtained by reading data stored in the memory cell array and correcting error bits of the data using an error correction code (ECC) decoder.

5. A nonvolatile memory device comprising:
a memory cell array including a plurality of blocks;
a battery configured to store and supply power;
a trigger circuit configured to control the memory cell array to be refreshed selectively;
a page buffer configured to receive a refresh command from the trigger circuit; and
a control logic configured to refresh the memory cell array using the power provided by the battery without requiring an external power supply voltage.

6. The nonvolatile memory device of claim 5, wherein the trigger circuit includes a sensing unit configured to sense a state of the memory cell array and provide a refresh trigger signal based on a result value indicating the state of the memory cell array sensed by the sensing unit.

7. The nonvolatile memory device of claim 5, wherein the refreshing of the memory cell array does not use error bit-corrected data and increases threshold voltages of degraded nonvolatile memory cells using a second verify voltage that is greater than a first verify voltage used for data program verification.

8. The nonvolatile memory device of claim 7, wherein the second verify voltage is a median voltage of a minimum threshold voltage and a maximum threshold voltage of a program data distribution.

9. The nonvolatile memory device of claim 5, wherein the memory cell array is refreshed using data obtained by reading data stored in the memory cell array and correcting error bits of the data using an FCC decoder.

10. The nonvolatile memory device of claim 5, wherein the control logic is configured to periodically refresh the memory cell array without sensing the state of the memory cell array.

11. The nonvolatile memory device of claim 10, wherein the memory cell array is refreshed periodically in synchronization with an internal clock of the nonvolatile memory device.

12. The nonvolatile memory device of claim 5, wherein the battery is a micro battery or a micro capacitor.

13. A memory card comprising:
a nonvolatile memory device including a memory cell array that includes a plurality of blocks;
a card interface configured to communicate with a host; and
a memory controller configured to control communication between the nonvolatile memory device and the card interface,
wherein the nonvolatile memory device includes,
a memory cell array including nonvolatile memory cells;
a battery not supplied with external power and configured to store a charged voltage;
a sensing unit configured to sense a degradation state of the nonvolatile memory cells of the memory cell array;
a trigger circuit configured to transmit a refresh trigger signal based on the sensing result; and
a control logic driven by the charged voltage supplied from the battery and configured to refresh the nonvolatile memory cells of the memory cell array using the charged voltage in response to the refresh trigger signal transmitted from the trigger circuit.

14. The memory card of claim 13, being a multimedia card (MMC), an eMMC, a secure digital (SD) card, or a universal serial bus (USB) drive.

15. A method of refreshing a nonvolatile memory device, the method comprising:
storing a charged voltage and providing the stored voltage to a nonvolatile memory device without an external power supply;
sensing a degradation state of memory cells of the nonvolatile memory device;
transmitting a refresh trigger signal to a control logic based on the sensing result; and
refreshing the nonvolatile memory cells using the stored voltage and without the external power supply, in response to the refresh trigger signal.

16. A nonvolatile memory device comprising:
a plurality of nonvolatile memory cells;
a battery configured to store a voltage;
control logic configured to refresh at least one of the plurality of memory cells using the battery without requiring an external power source.

17. The nonvolatile memory device of claim 16, wherein the control logic is configured to sense a degradation state of the at least one of the plurality of nonvolatile memory cells and configured to refresh the at least one of the plurality of memory cells based on the sensed degradation state.

18. The nonvolatile memory device of claim 16, wherein the control logic is configured to refresh the at least one of the plurality of memory cells periodically.

19. The nonvolatile memory device of claim 18, wherein the control logic is configured to refresh in synchronization with an internal clock.
